(19) United States
(12) Patent Application Publication
(10) Pub. No.: US 2006/0284628 A1
(43) Pub. Date: Dec. 21, 2006

(54) Super element for the prediction of viscosity effect on crystal plate

(76) Inventor: Jiun-Der Yu, Sunnyvale, CA (US)

Correspondence Address: EPSON RESEARCH AND DEVELOPMENT INC;INTELLECTUAL PROPERTY DEPT, 2580 ORCHARD PARKWAY, SUITE 225, SAN JOSE, CA, 95131, US

(21) Appl. No.: 11/154,002

(22) Filed: Jun. 16, 2005

(51) Int. Cl. G01R 29/22

(52) U.S. Cl. 324/727

(57) ABSTRACT

A technique to calculate or predict the electric impedance and motional capacitance of resonating crystal plate using a “super element” enables significantly more accurate determination of these characteristics. A set of successively high-order two-dimensional equations is first derived from the three-dimensional equations of linear piezoelectricity with structural viscosity taken into account. To make the two-dimensional equations compatible with third-order plate theory, which is the preferred theory to use, the equations are truncated to third-order. When no viscosity considered, the third-order plate theory equations are solved using finite element (FE) method. The non-viscous solution is then used to construct a “super element,” which is employed to solve the third-order plate equations with viscosity. From the solution with viscosity, electric impedance and motional capacitance are calculated.

### BACKGROUND OF THE INVENTION

1. Field of the Invention

The present invention relates to a model and accompanying algorithm to predict the electric impedance and motional capacitance of a resonating crystal plate. The simulation model and algorithm may be implemented as a software program that is executed on a suitable computer.

2. Description of the Related Art

Traditional crystal plate analyses or numerical simulations do not consider the material viscosity of the crystal plate. Since single crystals usually have very low material viscosity, such traditional approaches typically predict reasonably accurate resonance frequencies and vibration modes. However, the traditional approaches are not useful in calculating motional capacitance or electric impedance; such approaches yield infinity and zero respectively for these terms, which, of course, is not reasonable. In addition, most polycrystalline ceramics have a much higher material viscosity than single crystals. These limitations make it difficult to compare the analysis or simulation results with experimental data or to use them in design. On an impedance analyzer (which is usually used to test the resonance frequency of a crystal plate resonator), the resonance is recognized as the local minimum of the impedance curve. However, a zero local impedance never appears. This is because the viscosity of a crystal plate always damps a little energy when the plate is vibrating.

### SUMMARY OF THE INVENTION

The present invention is directed to overcoming the above-described problems by providing an easy way to calculate the electric impedance and motional capacitance. Generally speaking, a set of successively high-order two-dimensional equations is first derived from the three-dimensional equations of linear piezoelectricity with structural viscosity taken into account. To make the two-dimensional equations compatible with third-order plate theory, which is the preferred theory to use, the equations are truncated to third-order. When no viscosity considered, the third-order plate theory equations are solved using finite element (FE) method. The non-viscous solution is then used to construct a “super element,” which is employed to solve the third-order plate equations with viscosity. From the solution with viscosity, electric impedance and motional capacitance are calculated.

According to one aspect of this invention, a method for determining at least one of electric impedance or motional capacitance of a crystal plate is provided. In one embodiment, the method comprises the steps of: deriving or obtaining a set of equations with which to analyze the crystal plate; solving the set of equations, without considering viscosity of the crystal plate, to obtain a non-viscous solution; constructing a super element using the non-viscous solution; solving the set of equations, considering viscosity of the crystal plate and using the super element, to obtain a viscous solution; and determining the electric impedance and/or the motional capacitance of the crystal plate using the viscous solution.

In obtaining the non-viscous solution, the set of equations are preferably solved using FE method and without considering an excitation voltage applied to the crystal plate. The non-viscous solution preferably yields resonance frequencies and corresponding vibration modes of the crystal plate.

Preferably, the constructed super element is a single finite element with the non-viscous solution as a weight function.

In another embodiment, the method comprises the steps of: deriving or obtaining a set of equations with which to analyze the crystal plate; solving the set of equations with viscosity set to zero to obtain at least one vibration mode of the inviscid crystal plate; constructing a super element using the obtained vibration mode(s) of the inviscid crystal plate; evaluating the impedance characteristics of each obtained vibration mode using the super element; solving the set of equations to obtain a viscous solution; and determining the electric impedance and/or the motional capacitance of the crystal plate using the viscous solution.

In obtaining the non-viscous solution, the set of equations are preferably solved using FE method and without an excitation voltage applied to the crystal plate. The non-viscous solution preferably yields vibration modes of the inviscid crystal plate.

Preferably, the constructed super element is a single finite element.

Another aspect of the invention is that any of the above methods can be performed by an appropriate device in response to execution of a set of instructions that are contained on a medium or waveform. That is, any of the methods or steps thereof may be executed on a computer or other processor-controlled device as directed by a set of instructions that may be stored on, or conveyed to, the computer or other processor-controlled device for execution. The set of instructions may be in the form of software. Alternatively, the instruction set may be embodied directly in hardware (e.g., an application specific integrated circuit (ASIC), digital signal processing circuitry, logic circuits, etc.), or such the instruction set may be implemented as a combination of software and hardware.

In another aspect, the invention involves an apparatus for determining at least one of electric impedance or motional capacitance of a crystal plate, the apparatus comprising one or more components or modules configured to: construct a super element using the non-viscous solution; solve the set of equations, considering viscosity of the crystal plate and using the super element, to obtain a viscous solution; and determine at least one of the electric impedance or the motional capacitance of the crystal plate using the viscous solution.

The operations performed by the component(s) or module(s) may be specified by a program of instructions embodied in software, hardware, or combination thereof. Also, the component(s)/module(s) may be embodied in a processor and possibly other components, such as memory, co-processor, etc., operating in conjunction with the processor to perform the recited functions.

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings wherein like reference symbols refer to like parts:

FIG. 1 is a crystal plate within a rectangular coordinate system;

FIG. 2 is a flow chart illustrating an algorithm for determining one or both of the electric impedance or the motional capacitance of a crystal plate according to at least one embodiment of the invention;

FIG. 3 is a simulation result showing the relation between the plate aspect ratio a/b (i.e., the length to thickness ratio) and the dimensionless natural frequencies;

FIG. 4 is a simulation result showing the predicted real part of the impedance at various aspect ratio; and

FIG. 5 is a block diagram illustrating an exemplary system that may be used to implement aspects of the present invention.

### DESCRIPTION OF THE PREFERRED EMBODIMENTS

### I. INTRODUCTION

This invention pertains to a model and accompanying algorithm to calculate or predict the electric impedance and motional capacitance of a resonating crystal plate. The crystal plate is analyzed considering neither its viscosity nor excitation voltage using finite element (FE) method, the result of which yields a displacement or mode shape, which, in turn, is used to construct a “super element.” The super element is used to calculate mode shape of the crystal plate with its viscosity and excitation voltage taken into account. This viscous solution is then used to calculate the electric impedance and the motional capacitance of the crystal plate.

### II. GOVERNING EQUATIONS OF PIEZOELECTRICITY

The 3-D equations of linear piezoelectricity comprise the field equations (1), the constitutive equations (2), and the gradient equations (3), which are set forth in the Appendix, along with all of the other numeral-identified equations referenced herein. In these equations, Tᵢⱼ, Sᵢⱼ, uᵢ, Dᵢ, and Eᵢ represent components of stress, strain, mechanical displacement, electric displacement, and electric field, respectively, and φ is the electric potential. Represented material properties include the elastic stiffness coefficients cᵢⱼₖₗ, the piezoelectric strain coefficients eᵢⱼₖ, the dielectric permittivities εᵢⱼ, and the mass density ρ.

In considering the viscosity effect of a crystal plate, it is assumed that the energy loss comes from a structural viscosity. Since only time-harmonic behaviors of a crystal plate are considered in this invention, it is convenient to consider a structural viscosity that is inversely proportional to the vibration frequency. With such a structural viscosity included, the constitutive stress equation becomes as set forth in (4), where c′ᵢⱼₖₗ represent the viscosity coefficients, ω the circular frequency, and cᵢⱼₖₗ^{c} the complex stiffness coefficients.

It will be appreciated that the only difference between the constitutive stress equations with and without viscosity is that in substitution of the complex stiffness coefficients for the elastic stiffness coefficients. In fact, setting the imaginary parts of the complex stiffness coefficients in the viscosity-included equation (4) to zero yields the viscosity-excluded equation (2). Hereinafter, the complex coefficient cᵢⱼₖₗ^{c} will be written as just cᵢⱼₖₗ for brevity.

To present the modified higher-order plate equation it is convenient to use the variational principal, i.e., for a region V bounded by a surface S, as set forth in equation (5), where K is the kinetic energy density given by equation (6), and H is the electric enthalpy density given by equation (7). Substituting the equations for H and K into equation (5) yields equation (8). The variational principle in (8) is employed in the next section to derive the higher-order plate equations.

### III. TWO-DIMENSIONAL EQUATIONS

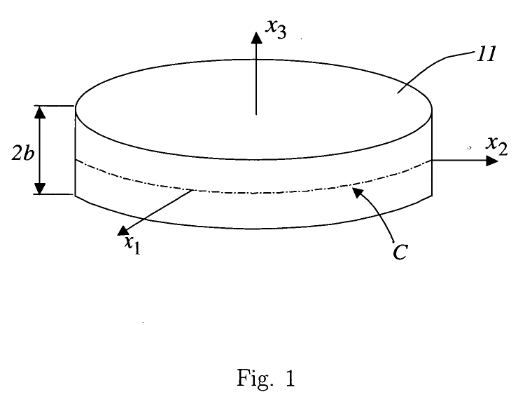

As shown in FIG. 1, the crystal plate 11 is modeled in a 3-D rectangular coordinate system defined by the dimensions x₁, x₂, x₃. Plate 11 has an edge denoted by C, with the upper and lower faces at x₃=±b. The components of displacement and electric potential are expanded into power series of the thickness coordinate x₃, as shown in equations (9), where \overline{V}₀ and \overline{V}₁ are determined by the driving voltage applied to crystal plate 11. As compared with other expansions that have been used, the expansion in (9) allows a stronger coupling between the electric and mechanical fields, and hence results in more accurate impedance prediction. Substitution of the equations in (9) into the corresponding ones in (3) yields the equations in (10), where the terms defined in (11) are the two-dimensional strains and electric fields of order n.

By substituting (9) into (8) and setting dV=dx₃dA, equation (12) is obtained, where the components of the n^{th}-order stress Tᵢⱼ⁽ⁿ⁾, the electric displacement Dᵢ⁽ⁿ⁾, the face traction Fⱼ⁽ⁿ⁾, the edge traction tⱼ⁽ⁿ⁾, and the edge charge σ⁽ⁿ⁾ are defined as set forth in (13), and Bₘₙ is as set forth in equation (14).

For independent variations δuⱼ⁽ⁿ⁾ and δφ⁽ⁿ⁾ in A, equation (12) implies the relationship in (15).

Similarly, the stationary value of the boundary integral (the second part of equation (12)) along edge C implies the natural edge conditions defined by equation (16), or the alternative essential edge conditions set forth in (17), where a=1,2, and the barred quantities represent the specified values on C.

Two-dimensional constitutive equations of order n are obtained by substituting (10) into (2) to yield the equations of (18). Note that the elastic stiffness coefficients cᵢⱼₖₗ are complex since plate viscosity is included.

Two-dimensional kinetic energy density \overline{K} and electric enthalpy density \overline{H} are defined as set forth in (19). Upon substituting (9) and (11) into (6) and (7), and the result into the equations in (19) yields the equations in (20) for \overline{K} and \overline{H}.

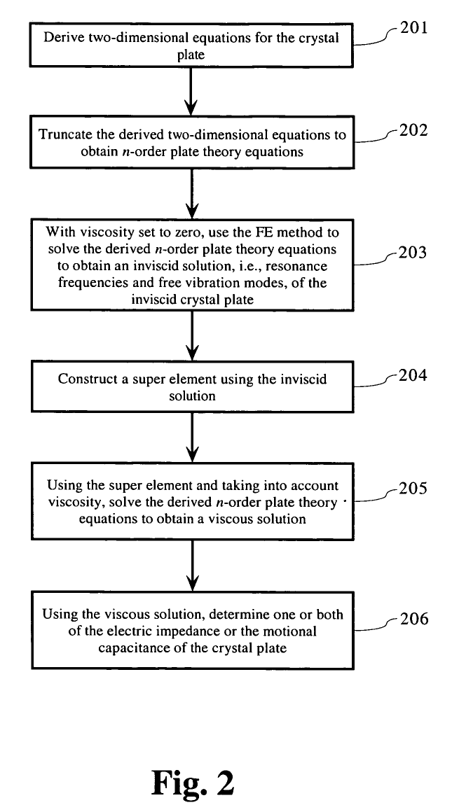

The formulation and derivation of the two-dimensional-equations constitute step 201 in the flow chart of FIG. 2.

The above-derived two-dimensional equations are truncated to obtain the zeroth-, first-, second-, third-, or higher-order plate theory equations (step 202). To which order to truncate depends on the vibration mode and the accuracy required. In the following sections, the concentration is on the viscosity analysis using the third-order theory. Hence, here the truncated third-order equations are set forth. For third-order plate theory, the conditions set forth in (21) are applicable. Note that the mass ratio R, defined to be the ratio of the electrode mass to the plate mass per unit area, has been added to the right hand side of the equations of motion to include the mass effect of the electrodes. The stress equations of motion, the charge equations, the constitutive equations, and the gradient equations, each truncated to the third-order are set forth in (22), (23), (24), and (25), respectively.

### IV. FINITE ELEMENT IMPLEMENTATION

The first step of the viscosity analysis is to set the structural viscosity to zero and use the FE method to solve the derived third-order plate theory for free vibration (step 203). The free vibration modes of the plate with no viscosity are employed to obtain the solution for the plate with structural viscosity. This section describes the procedure of applying FE methods to solve the third-order plate equations with \overline{V}₀=\overline{V}₁=0 and ℑcᵢⱼₖₗ=0.

The generalized nth-order displacement field, strain, and stress are defined in (26). Accordingly, the generalized displacement vector, strain, and stress for the third-order plate theory is as set forth in (27). From the nth-order gradient relation (11), the equation in (28) is obtained, where the strain operators are defined as stated in (29). Hence, the generalized strain for the third-order plate theory is as set forth in (30).

The constitutive equation for the third-order plate theory can also be written in matrix form, as shown in (31), where relevant matrices are defined in (32).

From (5) and (20), the variational principle for the third-order theory is as stated in (33). In matrix form it can be written as expressed in (34), with relevant matrices defined as per (35) and (36).

With the conventional discretization procedure, the variational equation leads to the equation (37). The arbitrariness of δU^{T} implies the relationship of (38), where K, M, F_{C}, F_{A} are defined as \acute{p}er equation (39).

Equation (38) is the conventional FE equation. For free vibrations, by setting the forcing terms to zero and letting the solution be harmonic the eigenvalue problem of equation (40) is obtained, where ω is the angular frequency.

It should be noted that the geometry of plate 11 and the mechanical effect of the electrodes are taken care of in this step.

### V. SUPER ELEMENT

After solving the third-order theory without viscosity by the FE method in step 203, eigenvalues (resonance frequencies) and corresponding eigenvectors (vibration modes) are obtained. The next step is to evaluate the impedance characteristics of each mode, which is done using a “super element,” invented and developed by the inventor (step 204). The super element is a single special finite element with the solution without structural viscosity as the weight function. Since there is only one element, there is no need to solve any extra matrix system. For ease of presentation, homogenous boundary conditions are assumed in the following discussion. Hence, all boundary terms on C can be ignored. Let uⱼ⁽ⁿ⁾ and φ⁽ⁿ⁾ denoted the solution from the FE analysis. Considering that the material viscosity is usually very small, uⱼ⁽ⁿ⁾ and φ⁽ⁿ⁾ are confidently assumed to be very close to the solution with viscosity. Hence, the solution with viscosity effect for these terms is as set forth in (41), where C₀ is a parameter to determine. Substitution of (41) into (12) yields equation (42), where the ˜ denotes that those quantities are functions of ũⱼ⁽ⁿ⁾ and \tilde{φ}⁽ⁿ⁾. The arbitrary δC₀ implies equation (43). Applying the two-dimensional divergence theory and ignoring all of the boundary terms, equation (44) is obtained. Since only E₃⁽⁰⁾ contains the excitation voltage \overline{V}₁, the zeroth-order electric field is redefined as set forth in equation (45) to make the following formulations as simple as possible. Rearranging the excitation voltage term to the right side of equation (44), equation (46) is obtained. From equation (46) the value of C₀, and hence the solution with viscosity, is calculated (step 205).

### VI. IMPEDANCE AND CAPACITANCE

To obtain the plate impedance or motional capacitance, the surface charge must first be obtained.

The total surface charge on either the upper or the lower face of crystal plate 11 is given in equation (47). Since the crystal plate is usually thin, the value of D₂ is basically independent of x₃. From the definition of D₁⁽ⁿ⁾, equation (48) is obtained. If D₂ is not dependent on the thickness coordinate x₃, the left side of (48) can be integrated to obtain equation (49). Substitution of (49) into (47) gives equation (50). Hence, to calculate the surface charge, the electric displacement D₂⁽⁰⁾ and D₂⁽²⁾, which are obtained using the FE method and the super element, into equation (50) and evaluate the integral.

With the surface charge calculated, motional capacitance and/or electric impedance are then calculated (step 206). The motional capacitance is

$${C}_{m} = Q / \overline{{V}_{1}} ,$$

or as set forth in equation (51). The current I is the time derivative of the surface charge, so the impedance is calculated as set forth in equation (52).

### VII. NUMERICAL EXAMPLE

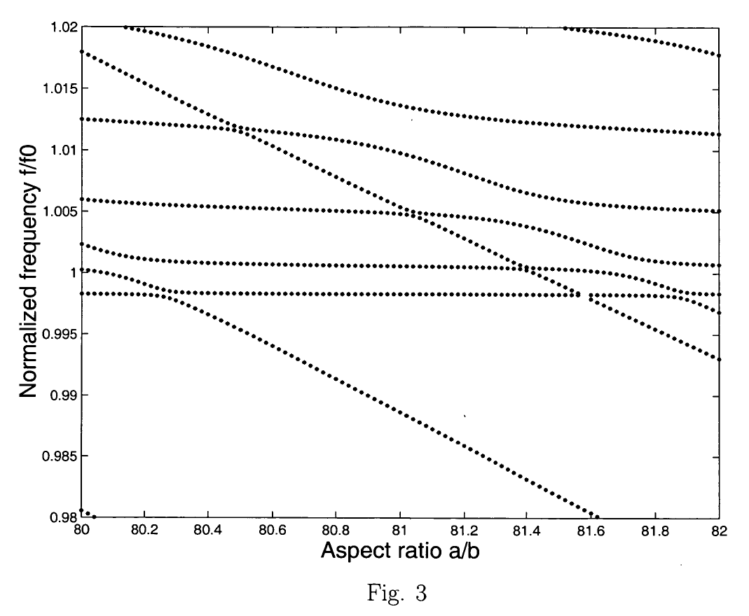

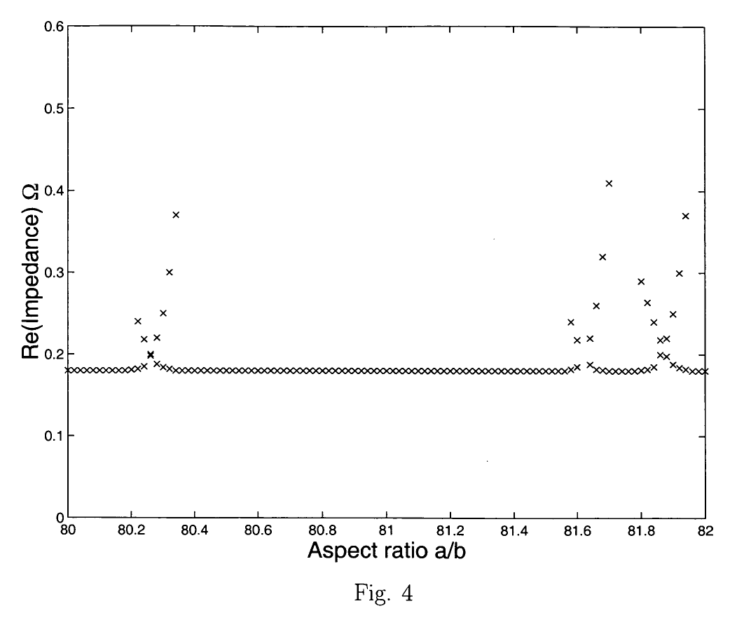

As a numerical example, consider the vibration of a rectangular AT-cut quartz plate of 80 microns thick and 3 millimeters wide. The quartz plate is coated with upper and lower aluminum electrodes, each about 785 angstroms thick. Since the densities of quartz and aluminum are 2649 Kg/m³ and 2699 Kg/m³ respectively, the mass ratio R in the right hand side of equation (21) is 0.002. The complex elastic stiffness coefficients (in contracted form), piezoelectric constants, and dielectric permittivities for AT-cut quartz are listed in equations (53), (54), and (55), respectively. The relation between the normalized vibration frequency and the length to thickness ratio a/b for the AT-cut plate without structural viscosity are shown in FIG. 3, where f0=20.68 MHz. The fundamental thickness shear mode, whose frequency is not influenced by the length to thickness ratio, has a normalized frequency of 0.998. This mode is strongly coupled with the flexural mode at a/b=80.25, 81.6, and 81.86. The real part of the predicted impedance for the fundamental thickness shear mode is shown in FIG. 4. Basically the impedance value is about 0.18 ohms if the mode is not coupled with the flexural mode. However, the value can be a lot higher at locations where the coupling becomes strong. Note also that the impedance is slightly lower when the a/b ratio is bigger, but the difference is so small that it cannot be seen on the figure.

### VIII. IMPLEMENTATIONS

As the foregoing demonstrates, the present invention provides an effective way to calculate the electric impedance and motional capacitance of a resonating crystal plate using a super element.

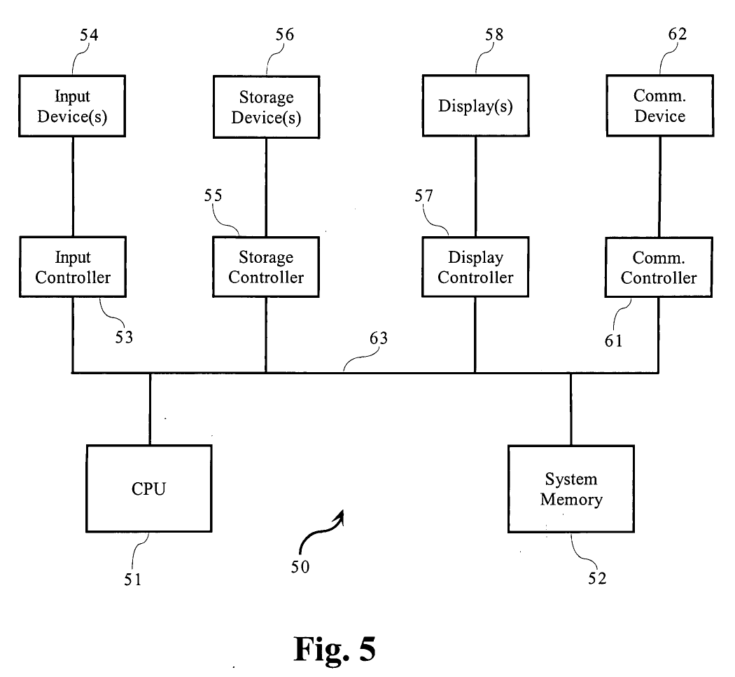

Having described the details of the invention, the discussion now turns to an exemplary system that may be used to implement the invention. Such a system 50 is shown in FIG. 5. As illustrated in FIG. 5, the system, which may be a computer or workstation, includes a central processing unit (CPU) 51 that provides computing resources and controls the system. CPU 51 may be implemented with a microprocessor or the like, and may represent more than one CPU, and may also include one or more auxiliary chips such as a graphics processor. System 50 further includes system memory 52, which may be in the form of random-access memory (RAM) and read-only memory (ROM).

A number of controllers and peripheral devices are also provided, as shown in FIG. 5. Input controller 53 represents an interface to various input devices 54, such as a keyboard, mouse, and/or stylus. A storage controller 55 interfaces with one or more storage devices 56, each of which includes a storage medium such as magnetic tape or disk, or an optical medium that may be used to record programs of instructions for operating systems, utilities and applications, which may include embodiments of programs that implement various aspects of the present invention. Storage device(s) 56 may also be used to store processed or data to be processed in accordance with the invention. A display controller 57 provides an interface to display device(s) 58, which may be of any known type, for viewing the simulation. A communications controller 61 interfaces with one or more communication devices 62 that enables system 50 to connect to remote devices through any of a variety of networks including the Internet, a local area network (LAN), a wide area network (WAN), or through any suitable electromagnetic carrier signals including infrared signals.

In the illustrated system, all major system components connect to bus 63 which may represent more than one physical bus. However, various system components may or may not be in physical proximity to one another. For example, input data and/or output data may be remotely transmitted from one physical location to another. Also, programs that implement various aspects of this invention may be accessed from a remote location (e.g., a server) over a network. Such data and/or programs may be conveyed through any of a variety of machine-readable medium including magnetic tape or disk or optical disc, network signals, or any other suitable electromagnetic carrier signals including infrared signals.

The present invention may be conveniently implemented with software. However, alternative implementations are certainly possible, including a hardware and/or a software/hardware implementation. Hardware-implemented functions may be realized using ASIC(s), digital signal processing circuitry, or the like. Accordingly, the phrase “components or modules” in the claims is intended to cover both software and hardware implementations. Similarly, the term “medium” as used herein includes software, hardware having a program of instructions hardwired thereon, or combination thereof. The instructions may be carried by a “waveform,” which includes any suitable electromagnetic carrier wave. With these implementation alternatives in mind, it is to be understood that the figures and accompanying description provide the functional information one skilled in the art would require to write program code (i.e., software) or to fabricate circuits (i.e., hardware) to perform the processing required.

While the invention has been described in conjunction with several specific embodiments, further alternatives, modifications, variations and applications will be apparent to those skilled in the art in light of the foregoing description. Thus, the invention described herein is intended to embrace all such alternatives, modifications, variations and applications as may fall within the spirit and scope of the appended claims.

$$\begin{matrix}{T}_{ij , i} = ρ {\ddot{u}}_{j} , {D}_{i , i} = 0 , & ( 1 ) \\ {T}_{ij} = {c}_{ijkl} {S}_{kl} - {e}_{kij} {E}_{k} , \\ {D}_{i} = {e}_{ijk} {S}_{jk} + {ε}_{ij} {E}_{j} , & ( 2 ) \\ {S}_{ij} = \frac{1}{2} ( {u}_{i , j} + {u}_{j , i} ) , {E}_{i} = - {ϕ}_{, i} . & ( 3 ) \\ \begin{matrix}{T}_{ij} = {c}_{ijkl} {S}_{kl} + \frac{{c}_{ijkl}^{′}}{ω} {\dot{S}}_{kl} - {e}_{kij} {E}_{k} , \\ = {c}_{ijkl} {S}_{kl} + {ic}_{ijkl}^{′} {S}_{kl} - {e}_{kij} {E}_{k} , \\ = {c}_{ijkl}^{c} {S}_{kl} - {e}_{kij} {E}_{k} ,\end{matrix} & ( 4 ) \\ δ {\int }_{{t}_{0}}^{{t}_{1}} ⅆ t {\int }_{V} ( K - H ) ⅆ V + {\int }_{{t}_{0}}^{{t}_{1}} {\int }_{S} ( {t}_{j} δ {u}_{j} + σδϕ ) ⅆ S = 0 , & ( 5 ) \\ K = \frac{1}{2} ρ {\dot{u}}_{j} {\dot{u}}_{j} , & ( 6 ) \\ H = \frac{1}{2} {c}_{ijkl} {S}_{ij} {S}_{kl} - \frac{1}{2} {ε}_{ij} {E}_{i} {E}_{j} - {e}_{ijk} {E}_{i} {S}_{jk} . & ( 7 ) \\ {\int }_{{t}_{0}}^{{t}_{1}} ⅆ t {\int }_{V} [ ( {T}_{ij , i} - ρ {\ddot{u}}_{j} ) δ {u}_{j} + {D}_{i , i} δ ϕ ] ⅆ V + {\int }_{{t}_{0}}^{{t}_{1}} ⅆ t {\int }_{S} [ ( {t}_{j} - {n}_{i} {T}_{ij} ) δ {u}_{j} + ( σ - {n}_{i} {D}_{i} ) δϕ ] ⅆ S = 0. & ( 8 ) \\ {u}_{i} = {\sum }_{n = 0}^{∞} {x}_{3}^{n} {u}_{i}^{( n )} ( {x}_{1} , {x}_{2} , t ) , \\ ϕ = {\overline{V}}_{0} + \frac{{x}_{3}}{b} {\overline{V}}_{1} + {\sum }_{n = 0}^{∞} {x}_{3}^{n} ( 1 - \frac{{x}_{3}^{2}}{{b}^{2}} ) {ϕ}^{( n )} ( {x}_{1} , {x}_{2} , t ) , & ( 9 ) \\ {S}_{ij} = {\sum }_{n = 0}^{∞} {x}_{3}^{n} {S}_{ij}^{( n )} , {E}_{i} = {\sum }_{n = 0}^{∞} {x}_{3}^{n} {E}_{i}^{( n )} , & ( 10 ) \\ {S}_{ij}^{( n )} = \frac{1}{2} [ {u}_{i , j}^{( n )} + {u}_{j , i}^{( n )} + ( n + 1 ) ( {δ}_{i 3} {u}_{j}^{( n + 1 )} + {δ}_{j 3} {u}_{i}^{( n + 1 )} ) ] , \\ {E}_{i}^{( n )} = - {ϕ}_{, i}^{( n )} + \frac{1}{{b}^{2}} {ϕ}^{( n - 2 )} + ( n + 1 ) {δ}_{i 3} ( \frac{1}{{b}^{2}} {ϕ}^{( n + 1 )} - {ϕ}^{( n + 1 )} ) - {δ}_{i 3} {δ}_{n 0} \frac{{\overline{V}}_{1}}{b} , & ( 11 ) \\ {\int }_{{t}_{0}}^{{t}_{1}} ⅆ t {\int }_{A} ⅆ A {\sum }_{n = 0}^{∞} [ ( {T}_{ij , i}^{( n )} - {nT}_{3 j}^{( n - 1 )} + {F}_{j}^{( n )} - ρ {\sum }_{m = 0}^{∞} {B}_{m m} {\ddot{u}}_{j}^{( m )} ) δ {u}_{j}^{( n )} + ( {D}_{i , i}^{( n )} - \frac{1}{{b}^{2}} {D}_{i , i}^{( n + 2 )} - {nD}_{3}^{( n - 1 )} + \frac{n + 2}{{b}^{2}} {D}_{3}^{( n + 1 )} ) {δϕ}^{( n )} ] + {\int }_{{t}_{0}}^{{t}_{1}} ⅆ t {\sum }_{n = 0}^{∞} {∮}_{C} ⅆ s [ ( {t}_{j}^{( n )} - {v}_{α} {T}_{aj}^{( n )} ) δ {u}_{j}^{( n )} + ( {σ}^{( n )} - \frac{1}{{b}^{2}} {σ}^{( n + 2 )} - {v}_{a} {D}_{α}^{( n )} + \frac{{v}_{α}}{{b}^{2}} {D}_{α}^{( n + 2 )} ) {δϕ}^{( n )} ] = 0. & ( 12 ) \\ {T}_{ ij}^{( n )} = {\int }_{- b}^{b} {x}_{3}^{n} {T}_{ij} ⅆ {x}_{3} , {D}_{i}^{( n )} = {\int }_{- b}^{b} {x}_{3}^{n} {D}_{i} ⅆ {x}_{3} , \\ {F}_{j}^{( n )} = {b}^{n} [ {T}_{3 j} ( {x}_{3} = b ) - {( - 1 )}^{n} {T}_{3 j} ( {x}_{3} = - b ) ] , \\ {t}_{j}^{( n )} = {\int }_{- b}^{b} {x}_{3}^{n} {t}_{j} ⅆ {x}_{3} , {σ}^{( n )} = {\int }_{- b}^{b} {x}_{3}^{n} σ ⅆ {x}_{3} , & ( 13 ) \\ {B}_{m m} = \{ \begin{matrix}\frac{2 {b}^{m + n + 1}}{m + n + 1} & m + n = even \\ 0 & m + n = odd .\end{matrix} & ( 14 ) \\ {T}_{ij , i}^{( n )} - {nT}_{3 j}^{( n - 1 )} + {F}_{j}^{( n )} = ρ {\sum }_{m = 0}^{∞} {B}_{m n} {\ddot{u}}_{j}^{( m )} \\ {D}_{i , i}^{( n )} - \frac{1}{{b}^{2}} {σ}_{i , i}^{( n + 2 )} - {nD}_{3}^{( n - 1 )} + \frac{n + 2}{{b}^{2}} {D}_{3}^{( n + 1 )} = 0 , & ( 15 ) \\ {t}_{j}^{( n )} - {v}_{α} {T}_{aj}^{( n )} , \\ {σ}^{( n )} - \frac{1}{{b}^{2}} {σ}^{( n + 2 )} = {v}_{α} ( {D}_{α}^{( n )} - \frac{1}{{b}^{2}} {D}_{α}^{( n + 2 )} ) on C & ( 16 ) \\ {u}_{j}^{( n )} = {\overline{u}}_{j}^{( n )} , {ϕ}^{( n )} = {\overline{ϕ}}^{( n )} on C , & ( 17 ) \\ {T}_{ij}^{( n )} = {\sum }_{m = 0}^{∞} {B}_{mn} ( {c}_{ijkl} {S}_{kl}^{( m )} - {e}_{kij} {E}_{k}^{( m )} ) , \\ {D}_{i}^{( n )} = {\sum }_{m = 0}^{∞} {B}_{mn} ( {e}_{ijk} {S}_{jk}^{( m )} - {ε}_{ij} {E}_{j}^{( m )} ) , & ( 18 ) \\ \overline{K} = {\int }_{- b}^{b} K ⅆ {x}_{3} , \overline{H} = {\int }_{- b}^{b} H ⅆ {x}_{3} , & ( 19 ) \\ \overline{K} = \frac{1}{2} {\sum }_{m , n} {B}_{m n} ρ {\dot{u}}_{j}^{( m )} {\dot{u}}_{j}^{( n )} , \\ \begin{matrix}\overline{H} = \frac{1}{2} {\sum }_{m , n = 0}^{∞} {B}_{mn} \\ ( {c}_{ijkl} {S}_{ij}^{( m )} {S}_{kl}^{( n )} - {ε}_{ij} {E}_{i}^{( m )} {E}_{j}^{( n )} - 2 {e}_{ijk} {E}_{i}^{( m )} {S}_{jk}^{( n )} ) \\ = \frac{1}{2} {\sum }_{n = 0}^{∞} ( {T}_{ij}^{( n )} {S}_{ij}^{( n )} - {D}_{i}^{( n )} {E}_{i}^{( n )} )\end{matrix} & ( 20 ) \\ {u}_{i}^{( n )} = {ϕ}^{( n )} = 0 , {T}_{ij}^{( n )} = {S}_{ij}^{( n )} = 0 , n > 3. & ( 21 ) \\ {T}_{ij , i}^{( 0 )} + {F}_{j}^{( 0 )} = ρ [ 2 b ( 1 + R ) {\ddot{u}}_{j}^{( 0 )} + \frac{2 {b}^{3}}{3} ( 1 + 3 R ) {\ddot{u}}_{j}^{( 2 )} ] , \\ {T}_{ij , i}^{( 1 )} - {T}_{3 j}^{( 0 )} + {F}_{j}^{( 1 )} = ρ [ \frac{2 {b}^{3}}{3} ( 1 + 3 R ) {\ddot{u}}_{j}^{( 1 )} + \frac{2 {b}^{5}}{5} ( 1 + 5 R ) {\ddot{u}}_{j}^{( 3 )} ] , \\ {T}_{ij , i}^{( 2 )} - 2 {T}_{3 j}^{( 1 )} + {F}_{j}^{( 2 )} = ρ [ \frac{2 {b}^{3}}{3} ( 1 + 3 R ) {\ddot{u}}_{j}^{( 0 )} + \frac{2 {b}^{5}}{5} ( 1 + 5 R ) {\ddot{u}}_{j}^{( 2 )} ] , \\ {T}_{ij , i}^{( 3 )} - 3 {T}_{3 j}^{( 2 )} + {F}_{j}^{( 3 )} = ρ [ \frac{2 {b}^{3}}{5} ( 1 + 5 R ) {\ddot{u}}_{j}^{( 1 )} + \frac{2 {b}^{7}}{7} ( 1 + 7 R ) {\ddot{u}}_{j}^{( 3 )} ] . & ( 22 ) \\ {D}_{i , i}^{( 0 )} - \frac{1}{{b}^{2}} {D}_{i , i}^{( 2 )} + \frac{2}{{b}^{2}} {D}_{3}^{( 1 )} = 0 , \\ {D}_{i , i}^{( 1 )} - \frac{1}{{b}^{2}} {D}_{i , i}^{( 3 )} - {D}_{3}^{( 0 )} + \frac{3}{{b}^{2}} {D}_{3}^{( 2 )} = 0 , \\ {D}_{i , i}^{( 2 )} - \frac{1}{{b}^{2}} {D}_{i , i}^{( 4 )} - 2 {D}_{3}^{( 1 )} + \frac{4}{{b}^{2}} {D}_{3}^{( 3 )} = 0 , \\ {D}_{i , i}^{( 3 )} - 3 {D}_{3}^{( 2 )} = 0. & ( 23 ) \\ {T}_{ij}^{( 0 )} = {c}_{ijkl} ( 2 {bS}_{kl}^{( m )} + \frac{2 {b}^{3}}{3} {S}_{kl}^{( 2 )} ) - {e}_{kij} ( 2 {bE}_{k}^{( 0 )} + \frac{2 {b}^{3}}{3} {E}_{k}^{( 2 )} ) , \\ {T}_{ij}^{( 1 )} = {c}_{ijkl} ( \frac{2 {b}^{3}}{3} {S}_{kl}^{( 1 )} + \frac{2 {b}^{5}}{5} {S}_{kl}^{( 3 )} ) - {e}_{kij} ( \frac{2 {b}^{3}}{3} {E}_{k}^{( 1 )} + \frac{2 {b}^{5}}{5} {E}_{k}^{( 3 )} ) , \\ {T}_{ij}^{( 2 )} = {c}_{ijkl} ( \frac{2 {b}^{3}}{3} {S}_{kl}^{( 0 )} + \frac{2 {b}^{5}}{5} {S}_{kl}^{( 2 )} ) - {e}_{kij} ( \frac{2 {b}^{3}}{3} {E}_{k}^{( 0 )} + \frac{2 {b}^{5}}{5} {E}_{k}^{( 2 )} ) , \\ {T}_{ij}^{( 3 )} = {c}_{ijkl} ( \frac{2 {b}^{5}}{5} {S}_{kl}^{( 1 )} + \frac{2 {b}^{7}}{7} {S}_{kl}^{( 3 )} ) - {e}_{kij} ( \frac{2 {b}^{5}}{5} {E}_{k}^{( 1 )} + \frac{2 {b}^{7}}{7} {E}_{k}^{( 3 )} ) , \\ {D}_{i}^{( 0 )} = {e}_{ijk} ( 2 {bS}_{jk}^{( 0 )} + \frac{2 {b}^{3}}{3} {S}_{jk}^{( 2 )} ) - {ε}_{ij} ( 2 {bE}_{j}^{( 0 )} + \frac{2 {b}^{3}}{3} {E}_{j}^{( 2 )} ) , \\ {D}_{i}^{( 1 )} = {e}_{ijk} ( \frac{2 {b}^{3}}{3} {S}_{jk}^{( 1 )} + \frac{2 {b}^{5}}{5} {S}_{jk}^{( 3 )} ) - {ε}_{ij} ( \frac{2 {b}^{3}}{3} {E}_{j}^{( 1 )} + \frac{2 {b}^{5}}{5} {E}_{j}^{( 3 )} ) , \\ {D}_{i}^{( 2 )} = {e}_{ijk} ( \frac{2 {b}^{3}}{3} {S}_{jk}^{( 0 )} + \frac{2 {b}^{5}}{5} {S}_{jk}^{( 2 )} ) - {ε}_{ij} ( \frac{2 {b}^{3}}{3} {E}_{j}^{( 0 )} + \frac{2 {b}^{5}}{5} {E}_{j}^{( 2 )} ) , \\ {D}_{i}^{( 3 )} = {e}_{ijk} ( \frac{2 {b}^{5}}{5} {S}_{jk}^{( 1 )} + \frac{2 {b}^{7}}{7} {S}_{jk}^{( 3 )} ) - {ε}_{ij} ( \frac{2 {b}^{5}}{5} {E}_{j}^{( 1 )} + \frac{2 {b}^{7}}{7} {E}_{j}^{( 3 )} ) , & ( 24 ) \\ {S}_{ij}^{( n )} = \frac{1}{2} [ {u}_{i , j}^{( n )} + {u}_{j , i}^{( n )} + ( n + 1 ) ( {δ}_{i 3} {u}_{j}^{( n + 1 )} + {δ}_{j 3} {u}_{i}^{( n + 1 )} ) ] for n = 0 , 1 , 2 , \\ {S}_{ij}^{( 3 )} = \frac{1}{2} ( {u}_{i , j}^{( 3 )} + {u}_{j , i}^{( 3 )} ) , \\ {E}_{i}^{( 0 )} = - {ϕ}_{, i}^{( 0 )} - {δ}_{i 3} {ϕ}^{( 1 )} - {δ}_{i 3} \frac{{\overline{V}}_{1}}{b} , \\ {E}_{i}^{( 1 )} = - {ϕ}_{, i}^{( 1 )} + 2 {δ}_{i 3} ( \frac{1}{{b}^{2}} {ϕ}^{( 0 )} - {ϕ}^{( 1 )} ) , \\ {E}_{i}^{( 2 )} = - {ϕ}_{, i}^{( 2 )} + \frac{1}{{b}^{2}} {ϕ}^{( 0 )} + 3 {δ}_{i 3} ( \frac{1}{{b}^{2}} {ϕ}^{( 1 )} - {ϕ}^{( 3 )} ) , \\ {E}_{i}^{( 3 )} = - {ϕ}_{, i}^{( 3 )} + \frac{1}{{b}^{2}} {ϕ}^{( 1 )} + {δ}_{i 3} \frac{4}{{b}^{2}} {ϕ}^{( 2 )} . & ( 25 ) \\ {u}^{( n )} = {\{ {u}_{1}^{( n )} , {u}_{2}^{( n )} , {u}_{3}^{( n )} , {ϕ}^{( n )} \}}_{4 \times 1} , \\ {S}^{( n )} = {\{ {S}_{1}^{( n )} , {S}_{2}^{( n )} , {S}_{3}^{( n )} , {S}_{4}^{( n )} , {S}_{5}^{( n )} , {S}_{6}^{( n )} , {E}_{1}^{( n )} , {E}_{2}^{( n )} , {E}_{3}^{( n )} \}}_{9 \times 1} , \\ {T}^{( n )} = {\{ {T}_{1}^{( n )} , {T}_{2}^{( n )} , {T}_{3}^{( n )} , {T}_{4}^{( n )} , {T}_{5}^{( n )} , {T}_{6}^{( n )} , {D}_{1}^{( n )} , {D}_{2}^{( n )} , {D}_{3}^{( n )} \}}_{9 \times 1} & ( 26 ) \\ u = {\{ {u}^{( 0 )} , {u}^{( 1 )} , {u}^{( 2 )} , {u}^{( 3 )} \}}_{16 \times 1} , \\ S = {\{ {S}^{( 0 )} , {S}^{( 1 )} , {S}^{( 2 )} , {S}^{( 3 )} \}}_{36 \times 1} , \\ T = {\{ {T}^{( 0 )} , {T}^{( 1 )} , {T}^{( 2 )} , {T}^{( 3 )} \}}_{36 \times 1} . & ( 27 ) \\ {S}^{( n )} = {δ}_{u} {u}^{( n )} + {δ}_{u}^{( n + 1 )} {u}^{( u + 1 )} + {δ}_{u}^{( n - 1 )} {u}^{( n - 1 )} , & ( 28 ) \\ {δ}_{u} = {[ \begin{matrix}\frac{\partial }{\partial {x}_{1}} & 0 & 0 & 0 \\ 0 & \frac{\partial }{\partial {x}_{2}} & 0 & 0 \\ 0 & 0 & 0 & 0 \\ 0 & 0 & \frac{\partial }{\partial {x}_{2}} & 0 \\ 0 & 0 & \frac{\partial }{\partial {x}_{1}} & 0 \\ \frac{\partial }{\partial {x}_{2}} & \frac{\partial }{\partial {x}_{1}} & 0 & 0 \\ 0 & 0 & 0 & - \frac{\partial }{\partial {x}_{1}} \\ 0 & 0 & 0 & - \frac{\partial }{\partial {x}_{2}} \\ 0 & 0 & 0 & 0\end{matrix} ]}_{9 \times 4} , {δ}_{u}^{( n + 1 )} = {( n + 1 ) [ \begin{matrix}0 & 0 & 0 & 0 \\ 0 & 0 & 0 & 0 \\ 0 & 0 & 1 & 0 \\ 0 & 1 & 0 & 0 \\ 1 & 0 & 0 & 0 \\ 0 & 0 & 0 & 0 \\ 0 & 0 & 0 & 0 \\ 0 & 0 & 0 & 0 \\ 0 & 0 & 0 & - 1\end{matrix} ]}_{9 \times 4} , \\ {δ}_{u}^{( n - 1 )} = {\frac{( n + 1 )}{{b}^{2}} [ \begin{matrix}0 & 0 & 0 & 0 \\ 0 & 0 & 0 & 0 \\ 0 & 0 & 0 & 0 \\ 0 & 0 & 0 & 0 \\ 0 & 0 & 0 & 0 \\ 0 & 0 & 0 & 0 \\ 0 & 0 & 0 & 0 \\ 0 & 0 & 0 & 0 \\ 0 & 0 & 0 & 1\end{matrix} ]}_{9 \times 4} & ( 29 ) \\ S = {[ \begin{matrix}{δ}_{u} & {δ}_{u}^{( 1 )} & 0 & 0 \\ {δ}_{u}^{( 0 )} & {δ}_{u} & {δ}_{u}^{( 2 )} & 0 \\ 0 & {δ}_{u}^{( 1 )} & {δ}_{u} & {δ}_{u}^{( 3 )} \\ 0 & 0 & {δ}_{u}^{( 2 )} & {δ}_{u}\end{matrix} ]}_{36 \times 16} {\{ \begin{matrix}{u}^{( 0 )} \\ {u}^{( 1 )} \\ {u}^{( 2 )} \\ {u}^{( 3 )}\end{matrix} \}}_{16 \times 1} & ( 30 ) \\ T = C S & ( 31 ) \\ C = {[ \begin{matrix}{B}_{00} \overline{C} & 0 & {B}_{02} \overline{C} & 0 \\ 0 & {B}_{11} \overline{C} & 0 & {B}_{13} \overline{C} \\ {B}_{20} \overline{C} & 0 & {B}_{22} \overline{C} & 0 \\ 0 & {B}_{31} \overline{C} & 0 & {B}_{33} \overline{C}\end{matrix} ]}_{36 \times 36} , \overline{C} = {[ \begin{matrix}c & - {e}^{T} \\ e & ε\end{matrix} ]}_{9 \times 9} & ( 32 ) \\ δ {\int }_{A} \frac{1}{2} {\sum }_{m , n = 0}^{3} {B}_{mn} [ ρ {\dot{u}}_{j}^{( m )} {\dot{u}}_{j}^{( n )} - ( {c}_{ijkl} {S}_{ij}^{( m )} {S}_{ij}^{( n )} - {ε}_{ij} {E}_{i}^{( m )} {E}_{j}^{( n )} - 2 {e}_{ijk} {E}_{i}^{( m )} {S}_{jk}^{( n )} ) ] ⅆ A + {\int }_{C}^{} {\sum }_{n = 0}^{3} [ {t}_{j}^{( n )} δ {u}_{j}^{( n )} + ( {σ}^{( n )} - \frac{1}{{b}^{2}} {σ}^{( n + 2 )} ) {δϕ}^{( n )} ] ⅆ s = 0. & ( 33 ) \\ {\int }_{A} δ {S}^{T} DS ⅆ A + {\int }_{A} ρδ {u}^{T} m \ddot{u} ⅆ A = {\int }_{C} δ {u}^{T} f ⅆ S + {\int }_{A} δ {f}^{T} F ⅆ A , & ( 34 ) \\ D = {[ \begin{matrix}{\overline{B}}_{00} \overline{D} & 0 & {\overline{B}}_{02} \overline{D} & 0 \\ 0 & {\overline{B}}_{11} \overline{D} & 0 & {\overline{B}}_{13} \overline{D} \\ {\overline{B}}_{20} \overline{D} & 0 & {\overline{B}}_{22} \overline{D} & 0 \\ 0 & {\overline{B}}_{31} \overline{D} & 0 & {\overline{B}}_{33} \overline{D}\end{matrix} ]}_{36 \times 36} , \overline{D} = {[ \begin{matrix}c & - {e}^{T} \\ e & - ε\end{matrix} ]}_{9 \times 9} . & ( 35 ) \\ m = {[ \begin{matrix}{B}_{00} \overline{m} & 0 & {B}_{02} \overline{m} & 0 \\ 0 & {B}_{11} \overline{m} & 0 & {B}_{13} \overline{m} \\ {B}_{20} \overline{m} & 0 & {B}_{22} \overline{m} & 0 \\ 0 & {B}_{31} \overline{m} & 0 & {B}_{33} \overline{m}\end{matrix} ]}_{36 \times 36} , \overline{m} = ρ [ \begin{matrix}1 & 0 & 0 & 0 \\ 0 & 1 & 0 & 0 \\ 0 & 0 & 1 & 0 \\ 0 & 0 & 0 & 1\end{matrix} ] . & ( 36 ) \\ δ {U}^{T} ( {\int }_{A} {B}^{T} DB ⅆ AU + {\int }_{A} {N}^{T} mN ⅆ A \ddot{U} - {\int }_{C} {N}^{T} f ⅆ S - {\int }_{A} {N}^{T} F ⅆ A ) = 0. & ( 37 ) \\ KU + M \ddot{U} = {F}_{C} + {F}_{A} , & ( 38 ) \\ K = {\int }_{A} {B}^{T} DB ⅆ A , M = {\int }_{A} {N}^{T} mN ⅆ A , {F}_{C} = {\int }_{C} {N}^{T} f ⅆ S , , {F}_{A} = {\int }_{A} {N}^{T} F ⅆ A . & ( 39 ) \\ KU - {ω}^{2} MU = 0 , & ( 40 ) \\ {\tilde{u}}_{j}^{( n )} = {C}_{0} {u}_{j}^{( n )} , {\tilde{ϕ}}^{( n )} = {C}_{0} {ϕ}^{( n )} , & ( 41 ) \\ {\int }_{{t}_{0}}^{{t}_{1}} ⅆ t {\int }_{A} ⅆ A {\sum }_{n = 0}^{∞} [ ( {\tilde{T}}_{ij , i}^{( n )} - n {\tilde{T}}_{3 j}^{( n - 1 )} - ρ {\sum }_{m = 0}^{∞} {B}_{mn} {C}_{0} {\ddot{u}}_{j}^{( m )} ) {u}_{j}^{( n )} + ( {\tilde{D}}_{i , i}^{( n )} - \frac{1}{{b}^{2}} {\tilde{D}}_{i , i}^{( n + 2 )} - n {\tilde{D}}_{3}^{( n - 1 )} + \frac{n + 2}{{b}^{2}} {\tilde{D}}_{3}^{( n + 1 )} ) {ϕ}^{( n )} ] δ {C}_{0} = 0 , & ( 42 ) \\ {\int }_{A} ⅆ A {\sum }_{n = 0}^{∞} [ ( {\tilde{T}}_{ij , i}^{( n )} - n {\tilde{T}}_{3 j}^{( n - 1 )} - ρ {\sum }_{m = 0}^{∞} {B}_{mn} {C}_{0} {\ddot{u}}_{j}^{( m )} ) {u}_{j}^{( n )} + ( {\tilde{D}}_{i , i}^{( n )} - \frac{1}{{b}^{2}} {\tilde{D}}_{i , i}^{( n + 2 )} - n {\tilde{D}}_{3}^{( n - 1 )} + \frac{n + 2}{{b}^{2}} {\tilde{D}}_{3}^{( n + 1 )} ) {ϕ}^{( n )} ] = 0. & ( 43 ) \\ {\int }_{A} {\sum }_{n = 0}^{3} [ - {\tilde{T}}_{ij}^{( n )} {\tilde{S}}_{ij}^{( n )} - {\tilde{D}}_{i}^{( n )} {\tilde{E}}_{i}^{( n )} + {ρω}^{2} {C}_{0} {\sum }_{m = 0}^{3} {B}_{mn} {u}_{j}^{( m )} {u}_{j}^{( n )} ] ⅆ A = 0. & ( 44 ) \\ {E}_{i}^{( 0 )} = - {ϕ}_{, i}^{( 0 )} - {δ}_{i 3} {ϕ}^{( 1 )} , & ( 45 ) \\ {\int }_{A} {\sum }_{n = 0}^{3} [ {T}_{ij}^{( n )} {S}_{ij}^{( n )} - {D}_{i}^{( n )} {E}_{i}^{( n )} - {ρω}^{2} {\sum }_{m = 0}^{3} {B}_{mn} {u}_{j}^{( m )} {u}_{j}^{( n )} ] ⅆ A {C}_{0} = {\int }_{A} [ {D}_{3}^{( 0 )} + 2 b {ε}_{i 3} ( {E}_{i}^{( 0 )} - {δ}_{i 3} \frac{{\overline{V}}_{1}}{b} ) + \frac{2 {b}^{3}}{3} {ε}_{i 3} {E}_{i}^{( 2 )} ] \frac{{\overline{V}}_{1}}{b} ⅆ A . & ( 46 ) \\ Q = {\int }_{A} {D}_{2} {\vert}_{{x}_{3} = b} ⅆ A . & ( 47 ) \\ {\int }_{- b}^{b} ( 1 - \frac{{x}_{3}^{2}}{{b}^{2}} ) {D}_{2} ⅆ {x}_{3} = {D}_{2}^{( 0 )} - \frac{1}{{b}^{2}} {D}_{2}^{( 2 )} . & ( 48 ) \\ {D}_{2} = \frac{3}{4 b} ( {D}_{2}^{( 0 )} - \frac{1}{{b}^{2}} {D}_{2}^{( 2 )} ) . & ( 49 ) \\ Q = \frac{3}{4 b} {\int }_{A} ( {D}_{2}^{( 0 )} - \frac{1}{{b}^{2}} {D}_{2}^{( 2 )} ) ⅆ A . & ( 50 ) \\ {C}_{m} = \frac{3}{4 b {\overline{V}}_{1}} {\int }_{A} ( {D}_{2}^{( 0 )} - \frac{1}{{b}^{2}} {D}_{2}^{( 2 )} ) ⅆ A . & ( 51 ) \\ Z = \frac{3 i ω}{4 b {\overline{V}}_{1}} {\int }_{A} ( {D}_{2}^{( 0 )} - \frac{1}{{b}^{2}} {D}_{2}^{( 2 )} ) ⅆ A & ( 52 ) \\ \begin{matrix}{c}_{11} = ( 86.74 , 0.034 ) \times {10}^{9} N / {m}^{2} , & {c}_{12} = ( - 8.25 , 0.004 ) \times {10}^{9} N / {m}^{2} , \\ {c}_{13} = ( 27.15 , 0.014 ) , & {c}_{14} = ( - 3.66 , 0.0031 ) , \\ {c}_{22} = ( 129.77 , 0.043 ) , & {c}_{23} = ( - 7.42 , 0.0039 ) , \\ {c}_{24} = ( 5.7 , 0.0066 ) , & {c}_{33} = ( 102.83 , 0.0131 ) , \\ {c}_{34} = ( 9.92 , 0.007 ) , & {c}_{44} = ( 38.61 , 0.0091 ) , \\ {c}_{55} = ( 68.81 , 0.024 ) , & {c}_{56} = ( 2.53 , 0.0011 ) , \\ {c}_{66} = ( 29.01 , 0.014 ) , & {c}_{15} = {c}_{16} = {c}_{25} = {c}_{26} = {c}_{35} = {c}_{36} = {c}_{45} = {c}_{46} = 0 ,\end{matrix} & ( 53 ) \\ {e}_{ip} = ( \begin{matrix}0.171 & - 0.152 & - 0.0187 & 0.067 & 0 & 0 \\ 0 & 0 & 0 & 0 & 0.108 & - 0.095 \\ 0 & 0 & 0 & 0 & - 0.0761 & 0.067\end{matrix} ) C / {m}^{2} & ( 54 ) \\ {ε}_{ij} = ( \begin{matrix}39.21 & 0 & 0 \\ 0 & 39.82 & 0 \\ 0 & 0 & 40.42\end{matrix} ) \times {10}^{- 12} C / V \cdot m & ( 55 )\end{matrix}$$

What is claimed is:

1. A method for determining at least one of electric impedance or motional capacitance of a crystal plate, the method comprising the steps of:
(a) deriving or obtaining a set of equations with which to analyze the crystal plate;
(b) solving the set of equations, without considering viscosity of the crystal plate, to obtain a non-viscous solution;
(c) constructing a super element using the non-viscous solution;
(d) solving the set of equations, considering viscosity of the crystal plate and using the super element, to obtain a viscous solution; and
(e) determining at least one of the electric impedance or the motional capacitance of the crystal plate using the viscous solution.

2. The method of claim 1, wherein, in step (b), the set of equations are solved to obtain a non-viscous solution without an excitation voltage applied to the crystal plate.

3. The method of claim 1, wherein step (b) is carried out using a finite element method.

4. The method of claim 1, wherein the non-viscous solution obtained in step (b) yields resonance frequencies and corresponding vibration modes of the crystal plate.

5. The method of claim 1, wherein the super element constructed in step (c) is a single finite element with the non-viscous solution as a weight function.

6. The method of claim 4, wherein the super element constructed in step (c) is a single finite element with the non-viscous solution as a weight function.

7. A medium or waveform containing a set of instructions adapted to direct an appropriate device to perform the method of claim 1.

8. A method for determining at least one of electric impedance or motional capacitance of a crystal plate, the method comprising the steps of:
(a) deriving or obtaining a set of equations with which to analyze the crystal plate;
(b) solving the set of equations with viscosity set to zero to obtain at least one vibration mode of the inviscid crystal plate;
(c) constructing a super element using the at least one vibration mode of the inviscid crystal plate obtained in step (b);
(d) evaluating the impedance characteristics of each vibration mode obtained in step (b) using the super element;
(e) solving the set of equations to obtain a viscous solution; and
(f) determining at least one of the electric impedance or the motional capacitance of the crystal plate using the viscous solution.

9. The method of claim 8, wherein, in step (b), the set of equations are solved to obtain a non-viscous solution without an excitation voltage applied to the crystal plate.

10. The method of claim 8, wherein step (b) is carried out using a finite element method.

11. The method of claim 8, wherein, in step (b), a plurality of vibration modes of the inviscid crystal plate are obtained.

12. The method of claim 8, wherein the super element constructed in step (c) is a single finite element.

13. A medium or waveform containing a set of instructions adapted to direct an appropriate device to perform the method of claim 8.

14. An apparatus for determining at least one of electric impedance or motional capacitance of a crystal plate, the apparatus comprising one or more components or modules configured to:
solve a set of equations, without considering viscosity of the crystal plate, to obtain a non-viscous solution;
construct a super element using the non-viscous solution;
solve the set of equations, considering viscosity of the crystal plate and using the super element, to obtain a viscous solution; and
determine at least one of the electric impedance or the motional capacitance of the crystal plate using the viscous solution.

15. The apparatus or device of claim 14, wherein operations performed by the one or more components or modules are specified by a program of instructions embodied in software, hardware, or combination thereof.

16. The apparatus or device of claim 14, wherein the one or more components or modules comprises at least a processor.

17. The apparatus of claim 14, wherein the apparatus comprises a computer.
